(19) United States
(12) Patent Application Publication
(10) Pub. No.: US 2025/0089368 A1
(43) Pub. Date: Mar. 13, 2025

(54) SEMICONDUCTOR DEVICE, DISPLAY PANEL AND CHIP

(71) Applicant: WUHAN CHINA STAR OPTOELECTRONICS TECHNOLOGY CO., LTD., Wuhan, Hubei (CN)

(72) Inventors: Huihui ZHAO, Wuhan, Hubei (CN); Chunpeng ZHANG, Wuhan, Hubei (CN); Fei AI, Wuhan, Hubei (CN); Jianfeng YUAN, Wuhan, Hubei (CN); Zhifu LI, Wuhan, Hubei (CN)

(21) Appl. No.: 18/567,964

(22) PCT Filed: Sep. 26, 2023
(86) PCT No.: PCT/CN2023/121713

§ 371 Date: Dec. 7, 2023

(30) Foreign Application Priority Data
Sep. 6, 2023 (CN) 202311154006.X

(51) Int. Cl. H01L 27/12; H01L 29/66; H01L 29/786

(52) U.S. Cl. CPC H10D 86/60; H10D 30/0321; H10D 30/6713; H10D 30/6728; H10D 30/6745; H10D 30/6757; H10D 86/0221; H10D 86/421

(57) ABSTRACT

A semiconductor device, a display panel, and a chip are provided in embodiments of the present application. The semiconductor device of the embodiments of the present application stacks a first conductor portion, a channel portion, and a second conductor portion to form a vertical active structure layer to realize a narrow channel. A growth direction of crystal grains arranged in the channel potion is consistent with a moving direction of carriers to provide a single crystal-like channel.

### TECHNICAL FIELD

The present application relates to the field of display technologies, and more particularly, to a semiconductor device, a display panel and a chip.

### BACKGROUND

At present, chips made by manufacturers have high cost. Integrating MUX, SOURCE and TCON of a chip circuit on a glass substrate (SOG) can greatly improve integration of a display panel, depend less on the chip and reduce the cost. To realize SOG, it is necessary to improve the integration, maximum operating frequency and current density of existing thin film transistors (TFT). All these require TFT to have shorter channel length, higher mobility and smaller volume.

At present, most thin film transistors are amorphous silicon, metal oxide semiconductor and polysilicon, wherein polysilicon is used in mobile phones, VR and so on because of its high mobility and small device size. However, the mobility and size of polysilicon used in chip manufacturing cannot meet the requirements.

### SUMMARY

An embodiment of the present application provides a semiconductor device, a display panel, and a chip, for a short channel of a thin film transistor while improving a carrier mobility.

An embodiment of the present application provides a semiconductor device including:
a substrate; and
at least one thin film transistor disposed on the substrate; wherein the thin film transistor includes:
an active structure layer disposed on the substrate, the active structure layer includes a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier.

In some embodiments of the present application, a slope angle of the active structure layer ranges from 80° to 90°.

In some embodiments of the present application, a thickness of the channel portion ranges from 5 nm to 1 mm.

In some embodiments of the present application, the gate electrode includes a first gate electrode and a second gate electrode, wherein the first gate electrode is located on a side of the active structure layer, and the second gate electrode is located on another side of the active structure layer;
wherein in the direction parallel to the extension direction of the substrate, one side of the first conductor portion, one side of the channel portion, and one side of the second conductor portion are overlapped with the first gate electrode; another side of the first conductor portion, another side of the channel portion, and another side of the second conductor portion are overlapped with the second gate electrode.

In some embodiments of the present application, a thickness of the first insulating layer is less than a thickness of the first conductor portion.

In some embodiments of the present application, on both sides of the active structural layer, the first conductor portion is not provided on the side of the first gate and the second gate near the substrate.

In some embodiments of the present application, the active structure layer includes a first side and a second side oppositely disposed, the first gate electrode covers a side of the first insulating layer facing the first side, the second gate electrode covers a side of the first insulating layer facing the second side, the first insulating layer includes a top portion, wherein the top portion covers a side of the active structure layer away from the substrate;
in an orthographic projection direction of the semiconductor device, the first gate electrode and the second gate electrode are flush with a side of the top portion away from the substrate.

In some embodiments of the present application, at least two the thin film transistors are provided, and in an orthographic projection of the semiconductor device, the gate electrode and the active structure layer are alternately arranged at intervals along a first direction, wherein the first direction is perpendicular to a direction of a long axis of the channel portion;
each of the thin film transistors includes two gate electrodes, wherein in the same thin film transistor, one gate electrode is disposed on a side of the active structure layer, and another gate electrode is disposed on another side of the active structure layer;
the first electrode, the second electrode, and the gate electrode are shared by two adjacent thin film transistors.

In some embodiments of the present application, the semiconductor device further includes a first connecting portion provided in the same layer as the first conductor portion, the first connecting portion is connected to a side of the first conductor portion of at least two thin film transistors, and the first electrode is connected to the first connecting portion through a first via;
the semiconductor device further includes a second connecting portion provided in the same layer as the second conductor portion, the second connecting portion is connected to a side of the second conductor portion of at least two thin film transistors, and the second electrode is connected to the second connecting portion through a second via.

In some embodiments of the present application, the semiconductor device further includes a third connecting portion provided in the same layer as the gate electrode, the third connecting portion is connected to one side of the gate electrode of at least two thin film transistors;
in the orthographic projection direction of the semiconductor device, a second insulating layer is provided between the first connecting portion and the third connecting portion, the second insulating layer covers the first connecting portion and exposes the first conductor portion, and the third connecting portion is provided on a side of the second insulating layer away from the substrate.

In some embodiments of the present application, the semiconductor device further includes a fourth connecting portion and a fifth connecting portion, wherein the fourth connecting portion is provided in the same layer as the first conductor portion, and the fourth connecting portion is connected to another side of the first conductor portions of at least two thin film transistors;
the fifth connecting portion is provided in the same layer as the channel portion, and the fifth connecting portion is connected to a side of the channel portion of at least two thin film transistors;
the second connecting portion, the fourth connecting portion, and the fifth connecting portion extend in the first direction, and the second connecting portion, wherein the fourth connecting portion and the fifth connecting portion are overlapped in the orthographic projection direction of the semiconductor device.

In some embodiments of the present application, the channel portion and the second conductor portion extend in the direction of the long axis of the channel portion and cover a part of the second insulating layer.

In some embodiments of the present application, the first connecting portion, the fourth connecting portion and the first conductor portion are made of a same material and formed integrally, the second connecting portion and the second conductor portion are made of a same material and formed integrally, the third connecting portion and the gate electrode are made of a same material and formed integrally, and the fifth connecting portion and the channel portion are made of a same material and formed integrally.

The present application also provides a display panel including a semiconductor device as described above.

The semiconductor device includes:
a substrate; and
at least one thin film transistor disposed on the substrate; wherein the thin film transistor includes:
an active structure layer disposed on the substrate, the active structure layer includes a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier.

In some embodiments of the present application, a slope angle of the active structure layer ranges from 80° to 90°.

In some embodiments of the present application, a thickness of the channel portion ranges from 5 nm to 1 mm.

In some embodiments of the present application, the gate electrode includes a first gate electrode and a second gate electrode, wherein the first gate electrode is located on a side of the active structure layer, and the second gate electrode is located on another side of the active structure layer;
wherein in the direction parallel to the extension direction of the substrate, one side of the first conductor portion, one side of the channel portion, and one side of the second conductor portion are overlapped with the first gate electrode; another side of the first conductor portion, another side of the channel portion, and another side of the second conductor portion are overlapped with the second gate electrode.

In some embodiments of the present application, a thickness of the first insulating layer is less than a thickness of the first conductor portion.

In some embodiments of the present application, on both sides of the active structural layer, the first conductor portion is not provided on the side of the first gate and the second gate near the substrate.

The present application also provides a chip including a semiconductor device of any one of the above embodiments.

The semiconductor device includes:
a substrate; and
at least one thin film transistor disposed on the substrate; wherein the thin film transistor includes:
an active structure layer disposed on the substrate, the active structure layer includes a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier.

In some embodiments of the present application, a slope angle of the active structure layer ranges from 80° to 90°.

In some embodiments of the present application, a thickness of the channel portion ranges from 5 nm to 1 mm.

In some embodiments of the present application, the gate electrode includes a first gate electrode and a second gate electrode, wherein the first gate electrode is located on a side of the active structure layer, and the second gate electrode is located on another side of the active structure layer;
wherein in the direction parallel to the extension direction of the substrate, one side of the first conductor portion, one side of the channel portion, and one side of the second conductor portion are overlapped with the first gate electrode; another side of the first conductor portion, another side of the channel portion, and another side of the second conductor portion are overlapped with the second gate electrode.

In some embodiments of the present application, a thickness of the first insulating layer is less than a thickness of the first conductor portion.

In some embodiments of the present application, on both sides of the active structural layer, the first conductor portion is not provided on the side of the first gate and the second gate near the substrate.

### Beneficial Effects

The semiconductor device of the embodiments of the application adopts a stacking of a first conductor portion, a channel portion and a second conductor portion to define a vertical active structure layer and realize a narrow channel; and the growth direction of the crystal grains provided in the channel portion is consistent with the moving direction of the carriers, so that a single crystal-like channel structure can be realized, thereby improving the mobility of the carriers.

### BRIEF DESCRIPTION OF THE DRAWINGS

FIG. 1 is a schematic top view of a semiconductor device according to some embodiments of the present application;

FIG. 2 is a schematic sectional diagram taken along a line AA of FIG. 1;

FIG. 3 is a schematic sectional diagram taken along a line BB of FIG. 1;

FIG. 4 is a schematic structural diagram according to step B1 of a method for manufacturing a semiconductor device according to some embodiments of the present application;

FIG. 5 is a schematic structural diagram according to step B2 of a method for manufacturing a semiconductor device according to some embodiments of the present application;

FIG. 6 is a schematic structural diagram according to step B3 of a method for manufacturing a semiconductor device according to some embodiments of the present application;

FIG. 7 is a schematic structural diagram according to step B4 of a method for manufacturing a semiconductor device according to some embodiments of the present application;

FIG. 8 is a schematic structural diagram according to step B5 of a method for manufacturing a semiconductor device according to some embodiments of the present application; and

FIG. 9 is a schematic structural diagram according to step B6 of a method for manufacturing a semiconductor device according to some embodiments of the present application.

### DETAILED DESCRIPTION

In the following, the technical solutions in the embodiments of the present application are clearly and completely described in connection with the drawings in the embodiments of the present application. It will be apparent that the described embodiments are merely a part of the embodiments of the present application, rather than all the embodiments. Based on the embodiments in the present application, all other embodiments obtained by those skilled in the art without involving any inventive effort are within the scope of the present application. Furthermore, it should be understood that the specific embodiments described herein are for purposes of illustration and explanation only and are not intended to limit the application. In the present application, if not stated to the contrary, the terms such as “up” and “down” refer to the up and down in the actual operating or working state of the device, specifically the drawing direction in the drawings; the terms “first,” “second,” “third,” and the like are only used as signs and do not impose numerical requirements or establish an order.

The embodiments of the present application provide a semiconductor device, a display panel, and a chip, which are described in detail below. It should be noted that the description order of the following embodiments is not taken as a limitation to the preferred order of the embodiments.

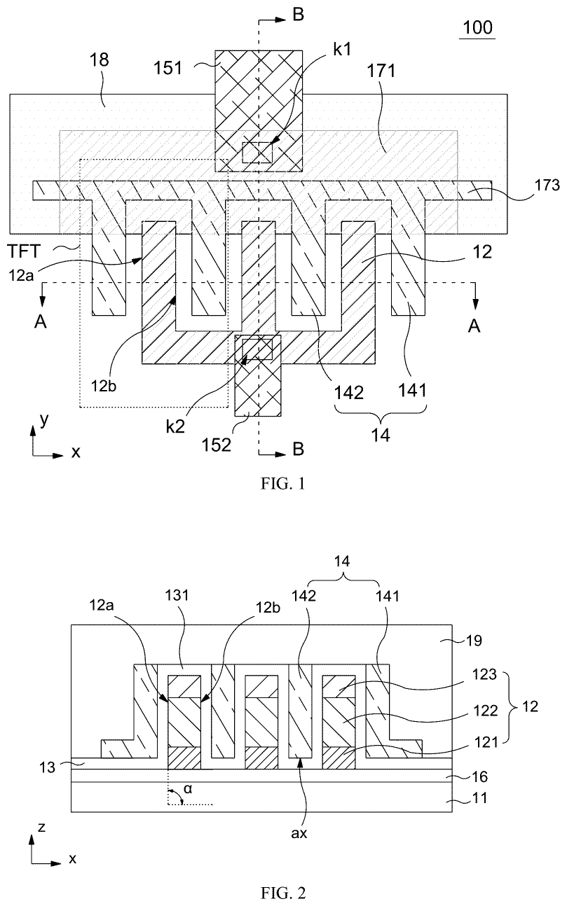

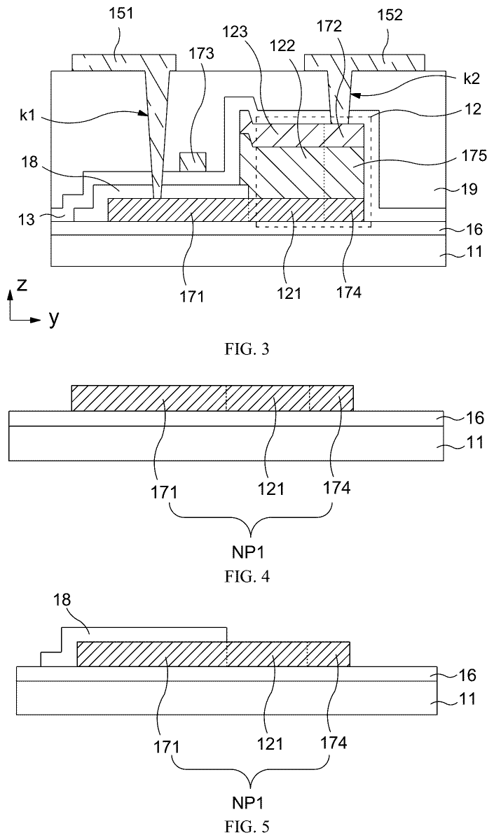

Referring to FIG. 1 to FIG. 3, some embodiments of the present application provide a semiconductor device 100 including a substrate 11 and at least one thin film transistor TFT. The thin film transistor TFT is provided on the substrate 11.

The thin film transistor TFT includes an active structure layer 12, a first insulating layer 13, a gate electrode 14, a first electrode 151, and a second electrode 152.

The active structure layer 12 is provided on the substrate 11. The active structure layer 12 includes a first conductor portion 121, a channel portion 122, and a second conductor portion 123. The first conductor portion 121 is provided on the substrate 11. The channel portion 122 is provided on a side of the first conductor portion 121 away from the substrate 11. The second conductor portion 123 is provided on a side of the channel portion 122 away from the substrate 11.

The first insulating layer 13 covers the active structure layer 12 and the substrate 11. A gate electrode 14 is provided on the first insulating layer 13 and on at least one side of the active structure layer 12. In an orthographic projection direction z perpendicular to the semiconductor device 100, the gate electrode 14 is overlapped with at least a side of the channel portion 122. The first electrode 151 is connected to the first conductor portion 121. The second electrode 152 is connected to the second conductor portion 123.

The channel portion 122 is made of polysilicon, and the crystal growth direction of the polysilicon coincides with the moving direction of the carriers.

In the semiconductor device 100 according to the embodiment of the present application, the first conductor portion 121, the channel portion 122, and the second conductor portion 123 are stacked to define a vertical active structure layer 12, that is, a thickness of the channel portion 122 is referred as a length of the channel, to provide a narrow channel. In addition, since the growth direction of the crystal grains of the channel portion 122 is the direction from the first conductor portion 121 to the second conductor portion 123 (the thickness direction of the channel portion 122), the crystal grains of the channel portion 122 are single crystal grains in the thickness direction of the channel portion 122, and the growth direction of the crystal grains of the channel portion 122 is provided to coincide with the moving direction of the carriers to realize a single crystal-like channel structure to improve the mobility of the carriers.

The crystal grains of the channel portion 122 are provided in a multi-grain arrangement parallel to the extension direction of the substrate 11.

It should be noted that the extension direction parallel to the substrate 11 is a first direction x. The thickness direction of each film layer is referred as the orthographic projection direction z of the semiconductor device 100. A direction of the long axis of the channel portion 122 is a second direction y. The first direction x and the second direction y intersect. Alternatively, the first direction x is perpendicular to the second direction y. In some embodiments, an angle between the first direction x and the second direction y is an acute angle.

In some embodiments, the slope angle α of the active structure layer 12 ranges from 80° to 90°. With this arrangement, the inversion carriers in the active structure layer are mainly concentrated on the surface, and the current from the source electrode to the drain electrode flows on the surface. Therefore, the slope angle α is controlled within a range of 80° to 90°, and the carriers can be ensured to move along the grain growth direction of the channel portion 122.

It should be understood, in a case that the slope angle α is too large or too small, the carriers move cross the grain boundaries, resulting in a decrease in mobility.

In some embodiments, the slope angle α may be 80, 81, 82, 83, 84,85, 86, 87, 88, 89, or 90°. In a case that the slope angle α is 90°, the mobility of the carriers is best.

In some embodiments, the thickness of the channel portion 122 ranges from 5 nm to 1 mm. It should be understood that in a case that the thickness of the channel portion 122 is too small, the short channel effect cannot be overcome, and in a case that the thickness of the channel portion is too large, it is difficult to form and crystallize. Therefore, the thickness of the channel portion 122 is selected between 5 nm to 1 mm, which can not only overcome the short channel effect, but also reduce the difficulty of film formation and crystallization.

In some embodiments, the thickness of the channel portion 122 may be 5 nm, 6 nm, 7 nm, 8 nm, 9 nm, 10 nm, 50 nm, 0.1 mm, 0.2 mm, 0.3 mm, 0.4 mm, 0.5 mm, 0.6 mm, 0.7 mm, 0.8 mm, 0.9 mm, or 1 mm.

In some embodiments, the materials of the first conductor portion 121 and the second conductor portion 123 may be polysilicon layers doped or implanted with conductive ions, and the conductive ions may be N-type doped ions or P-type doped ions, such as phosphorus ions, boron ions, gallium ions, indium ions, or the like.

It should be understood, the materials of the first conductor portion 121 and the second conductor portion 123 may be conductive materials, but are not limited thereto.

In some embodiments, the thickness of the first conductor portion 121 and the second conductor portion 123 respectively range from 30 nm to 300 nm, such as 30 nm, 40 nm, 50 nm, 60 nm, 70 nm, 80 nm, 90 nm, 100 nm, 150 nm, 200 nm, 250 nm, or 300 nm.

The thickness of the first conductor portion 121 and the second conductor portion 123 is selected within a range of 30 nm to 300 nm, which avoids the excessive resistance of the first conductor potion 121 and the second conductor potion 123, while also preventing excessively long time for film formation and heavily diffusion of particles.

In some embodiments, the material of the channel portion 122 may be other semiconductor materials, such as metal oxides.

In some embodiments, one of the first electrode 151 and the second electrode 152 is a source electrode, and another of the first electrode 151 and the second electrode 152 is a drain electrode.

The gate electrode 14, the first electrode 151, and the second electrode 152 may be formed using a metal element selected from chromium, copper, aluminum, gold, silver, zinc, molybdenum, tantalum, titanium, tungsten, manganese, nickel, iron, cobalt, an alloy containing any of the above metal elements, or an alloy combining any of the above metal elements. In addition, the gate electrode 14, the first electrode 151 and the second electrode 152 may have a single-layer structure or a stacked structure of two or more layers.

In some embodiments, the semiconductor device 100 may further include a buffer layer 16 disposed between the substrate 11 and the first conductor portion 121.

The first insulating layer 13 and the buffer layer 16 may be formed of a plurality of inorganic layers stacked in an alternating manner. For example, the first insulating layer 13 may be formed as a double layer by stacking an inorganic layer including at least one of silicon oxide, silicon nitride, silicon oxynitride, aluminum oxide, zirconium oxide, hafnium oxide, magnesium oxide, and titanium oxide, or a multilayer by alternately stacking an inorganic layer including at least one of silicon oxide, silicon nitride, silicon oxynitride, aluminum oxide, zirconium oxide, hafnium oxide, magnesium oxide, and titanium oxide. However, the present disclosure is not limited thereto, and the first insulating layer 13 and the buffer layer 16 may be formed as a single inorganic layer including the above-described insulating material.

In some embodiments, the substrate 11 may be a rigid substrate or a flexible substrate. Material of the substrate 11 include one of glass, sapphire, silicon, silica, polyethylene, polypropylene, polystyrene, polylactic acid, polyethylene dicarboxylate, polyethylene terephthalate, polyethylene naphthalate, polycarbonate, polyethersulfone, aromatic fluorotoluene containing polyarylate, polycyclic olefin, polyimide, or polyurethane.

In some embodiments, the gate electrode 14 includes a first gate electrode 141 and a second gate electrode 142. The first gate electrode 141 is located on a side of the active structure layer 12, and the second gate electrode 142 is located on another side of the active structure layer 12.

The thin film transistor TFT adopts dual-gate electrode control, which has a strong ability to control short channel effect and suppress leakage current, and has a strong electrostatic control capability for inversion channels.

In this case, in the orthogonal projection direction z of the semiconductor device 100, that is, in the first direction x, a side of the first conductor portion 121, a side of the channel portion 122, and a side of the second conductor portion 123 are overlapped with the first gate electrode 141. Another side of the first conductor portions 121, another side of the channel portion 122, and another side of the second conductor portion 123 are all overlapped with the second gate electrode 142.

The first grid electrode 141 and the second grid electrode 142 not only overlap with the channel portion 122, but also overlap with the first conductor portion 121 and the second conductor portion 123 to improve the control capability of the grid electrode 14.

In some embodiments, the active structure layer 12 includes a first side 12a and a second side 12b oppositely arranged. The first gate electrode 141 is covered on a side of the first insulating layer 13 facing the first side 12a. The second gate electrode 142 is covered on a side of the first insulating layer 13 facing the second side 12b. The first insulating layer 13 includes a top portion 131 covered a side of the active structure layer 12 away from the substrate 11.

In the orthographic projection direction z of the semiconductor device 100, the first gate electrode 141 and the second gate electrode 142 are flush with a side of the top portion 131 away from the substrate 11. Such an arrangement may improve the control capabilities of the first gate electrode 141 and the second gate electrode 142.

In some embodiments, the thickness of the first insulating layer 13 is less than the thickness of the first conductor portion 121. This arrangement enables the grid electrode 14 to overlap with a side of the first conductor potion 121 in the first direction x, so as to ensure that the grid electrode 14 has strong control capability.

In some embodiments, a groove or an opening may also be provided in the buffer layer 16, and the groove or the opening may be disposed on the respective side of the active structure layer 12, so that the first insulating layer 13 is covered in the groove or opening, so that the gate electrode 14 may overlap a side of the first conductor portion 121 in the first direction x, or even completely overlap a side of the first conductor portion 21.

In some embodiments, on both sides of the active structure layer 12, a side of the gate electrode 14 near the substrate 11 is not provided with the first conductor portion 121. This arrangement avoids the parasitic capacitance between the gate electrode 14 and the first conductor portion 121, and further avoids the gate-induced drain leakage (GIDL) effect.

In some embodiments, at least two thin film transistors TFT are provided. In the orthographic projection of the semiconductor device 100 (as shown in FIG. 1), the gate electrode 14 and the active structure layer 12 are alternately arranged at intervals along, the first direction x perpendicular to the direction of the long axis y of the channel portion 122.

Each thin film transistor TFT includes two gate electrodes 14. In the same thin film transistor TFT, one gate electrode 14 is provided on a side of the active structure layer 12, and another gate electrode 14 is provided on another side of the active structure layer 12.

The first electrode 151, the second electrode 152, and the gate electrode 14 are shared by two adjacent thin film transistors TFT. Such an arrangement may save material and layout space, and reduce process difficulty.

Since the active structure layer 12 is formed first and then the first insulating layer 13 is formed after, a recess ax is formed in the first insulating layer 13 and between adjacent active structure layers 12. The gate electrode 14 can be directly formed in the recess ax, and the upper and lower positions of the gate electrode 14 are determined by the depth of the recess ax. As such, the effect of self-aligning the gate electrode can be realized, thereby reducing the processing difficulty.

In some embodiments, the semiconductor device 100 further includes a first connecting portion 171 provided in the same layer as the first conductor portion 121. The first connecting portion 171 is connected to a side of the first conductor portions 121 of at least two thin film transistors TFT. The first electrode 151 is connected to the first connecting portion 171 through a first via k1.

The semiconductor device 100 further includes a second connecting portion 172 provided in the same layer as the second conductor portion 123. The second connecting portion 172 is connected to a side of the second conductor portions 123 of at least two thin film transistors TFT. The second electrode 152 is connected to the second connecting portion 172 through a second via k2.

The first conductor portion 121 and the first connecting portion 171 are provided in the same layer and connected, and they can be made of the same material and formed by using the same photomask. That is, the first connecting potion 171 and the first conductor potion 121 are made of the same material and integrally formed. In some embodiments, the first connecting potion 171 and the first conductor potion 121 may be provided in different layers, and their materials may also be different.

In some embodiments, the first via k1 is located at the center of the first connecting portion 171 so that the distance from the center of the first via k1 to each of the first conductor portions 121 is equal, thereby improving synchronization of signal transmission.

The second conductor portion 123 and the second connecting portion 172 are provided in the same layer and connected, and the materials of the two may be the same, and the two may be formed by using the same photomask. The second connecting portion 172 and the second conductor portion 123 are made of the same material and integrally formed. In some embodiments, the second connecting portion 172 and the second conductor portion 123 may also be provided in different layers, and their materials may also be different.

In some embodiments, the second via k2 is located at the center of the second connecting portion 172 so that the distance from the center of the second via k2 to each of the second conductor portions 123 is equal, thereby improving synchronization of signal transmission.

In some embodiments, in the orthographic projection of the semiconductor device 100, the orthographic projection of the first via k1 and the orthographic projection of the second via k2 are arranged symmetrically with respect to the first direction x, so that the distance for signal transmission can be shortened and the transmission rate of the signal can be increased.

In some embodiments, the first connecting portion 171 and the second connecting portion 172 both extend in the first direction x, the first conductor portion 121 and the second conductor portion 123 both extend in the second direction y, and the first direction x is perpendicular to the second direction y. This arrangement can reduce the layout space.

In some embodiments, the semiconductor device 100 further includes a third connecting portion 173 provided in the same layer as the gate electrode 14. The third connecting portion 173 is connected to one side of the gate electrodes 14 of at least two thin film transistors TFT.

In the orthographic projection direction z of the semiconductor device 100, a second insulating layer 18 is provided between the first connecting portion 171 and the third connecting portion 173. The second insulating layer 18 covers the first connecting portion 171 and exposes the first conductor portion 121, and the third connecting portion 173 is provided on a side of the second insulating layer 18 away from the substrate 11.

In some embodiments, the third connecting portion 173 and the gate electrode 14 are made of the same material and integrally formed. In some embodiments, the third connection 173 and the gate electrode 14 may also be provided in different layers, and the materials of the two may also be different.

In some embodiments, the semiconductor device 100 further includes a fourth connecting portion 174 and a fifth connecting portion 175. The fourth connecting portion 174 is provided in the same layer as the first conductor portion 121. The fourth connecting portion 174 is connected to another side of the first conductor portions 121 of at least two thin film transistors TFT.

That is, the first connecting portion 171 and the fourth connecting portion 174 are located on opposite sides of the first conductor portion 121.

The fifth connecting portion 175 is provided in the same layer as the channel portion 122. The fifth connecting portion 175 is connected to a side of each channel portion 122 of at least two thin film transistors TFT.

The second connecting portion 172, the fourth connecting portion 174, and the fifth connecting portion 175 all extend in the first direction x. In the orthographic projection direction z of the semiconductor device 100, the second connecting portion 172, the fourth connecting portion 174, and the fifth connecting portion 175 are overlapped.

The overlapping arrangement of the second connecting potion 172, the fourth connecting potion 174 and the fifth connecting potion 175 can improve the flatness and stability of the second connecting potion 172 and avoid the risk of disconnection of the second connecting potion 172 due to the step difference.

The fifth connecting portion 175 and the channel portion 122 are made of the same material and integrally formed. The first connecting portion 171, the fourth connecting portion 174 and the first conductor portion 121 are made of the same material and integrally formed.

In some embodiments, the channel portion 122 and the second conductor portion 123 extend along the direction of the long axis y of the channel portion 122 and cover a part of the second insulating layer 18.

It should be understood that in a case that the channel portion 122 and the second conductor portion 123 are patterned by a photolithography process, the pattern of the channel portion 122 and the pattern of the second conductor portion 123 may be shifted due to the alignment error of the photomask and the exposure error of the exposure machine. In a case that the pattern is designed just at the boundary of the second insulating layer 18, the pattern of the channel portion 122 and the pattern of the second conductor portion 123 may be actually shifted downward toward the boundary of the second insulating layer 18 due to the error. Then, during pattern etching, the etching liquid may continue to etch the first conductor portion after etching the channel portion and the second conductor layer, thereby causing the first conductor portion 121 to be disconnected from the first connecting portion 171.

The channel portion 122 and the second conductor portion 123 are used to overlap the second insulating layer 18 in order to overcome the error and ensure the effective connection between the first conductor portion 121 and the first connecting portion 171.

The manufacturing method of the semiconductor device 100 of this embodiment is as follows.

Referring to FIG. 4, in step B1, the buffer layer 16 and the patterned first conductor layer NP1 are sequentially formed on the substrate 11. The first conductor layer NP1 includes a first conductor portion 121, a first connecting portion 171, and a fourth connecting portion 174, and the first connecting portion 171 and the fourth connecting portion 174 are connected to opposite positions of the first conductor portion 121 in the second direction y.

Referring to FIG. 5, in step B2, a patterned second insulating layer 18 is formed on the first conductor layer NP1, and the second insulating layer 18 covers the first connecting portion 171, and exposes the first conductor portion 121 and the fourth connecting portion 174.

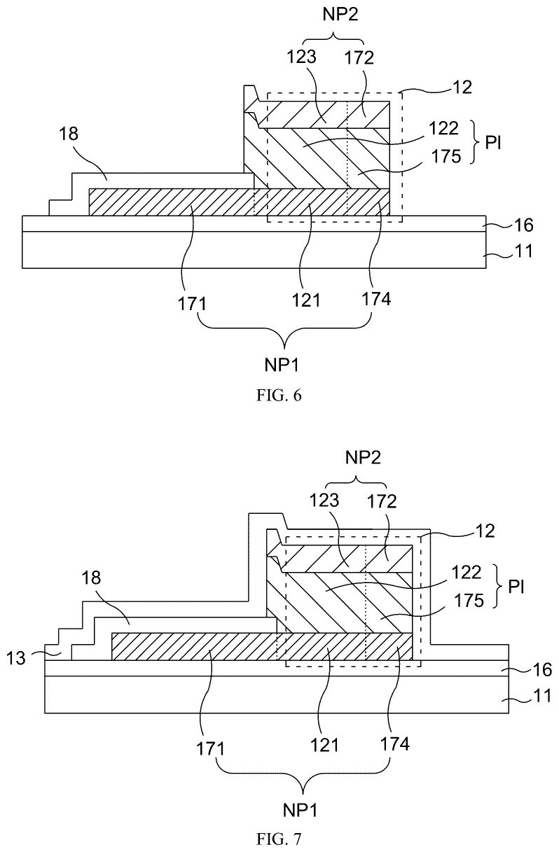

Referring to FIG. 6, in step B3, the channel layer P1 and the second conductor layer NP2 are sequentially formed on the buffer layer 16, and then the patterned channel layer P1 and the second conductor layer NP2 are formed using the same photomask. The channel layer P1 includes a channel portion 122 and a fifth connecting portion 175, and the second conductor layer NP2 includes a second conductor portion 123 and a second connecting portion 172. The first conductor portion 121, the channel portion 122, and the second conductor portion 123 are stacked to form the active structure layer 12.

Referring to FIG. 7, in step B4, a first insulating layer 13 is formed on the second conductor layer NP2. The first insulating layer 13 covers the active structure layer 12, the buffer layer 16, and the second insulating layer 18.

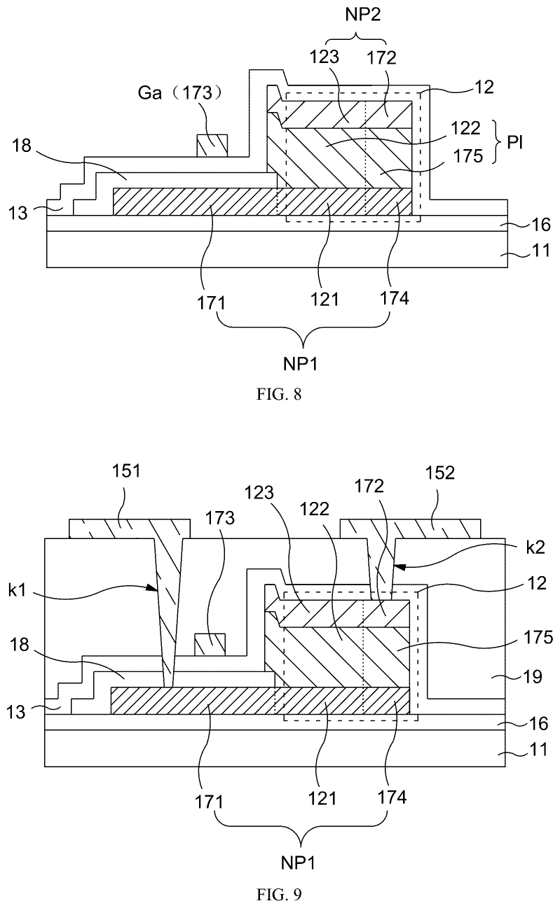

Referring to FIG. 8, in step B5, a patterned gate electrode layer Ga is formed on the second insulating layer 18. The gate electrode layer Ga includes a gate electrode 14 and a third connecting portion 173. The third connecting portion 173 is overlapped with the first connecting portion 171.

In some embodiments, the gate electrode layer Ga may be formed on an entire surface of the second insulating layer 18, the gate electrode layer Ga on a side of the active structure layer 12 away from the substrate 11 may be removed by a chemical mechanical polishing (CMP) technique, and a patterning process of a photolithography process may be performed on the gate electrode layer Ga to form the gate electrode 14 and the third connecting portion 173.

Referring to FIG. 9, in step B6, a third insulating layer 19 and a source/drain metal layer SD are sequentially formed on the gate electrode layer Ga, and the third insulating layer 19 covers the gate electrode layer Ga and the first insulating layer 13. The third insulating layer 19 is provided with a first via k1 and a second via k2. The first via k1 penetrates through the third insulating layer 19, the first insulating layer 13 and the second insulating layer 18, and the second via k2 penetrates through the third insulating layer 19 and the first insulating layer 13.

The source/drain metal layer SD includes a first electrode 151 and a second electrode 152. The first electrode 151 is connected to the first connection potion 171 through the first via k1, and the second electrode 152 is connected to the second connection potion 172 through the second via k2.

The above are the steps of the manufacturing method of the semiconductor device 100 according to the embodiment of the present application. In some embodiments, the first conductor layer NP1, the channel layer P1 and the second conductor layer NP2 may be sequentially formed and then a photomask process may be performed.

The embodiments of the present application further provide a display panel including the semiconductor device 100 according to any one of the above-described embodiments. That is, the structure of the semiconductor device of the display panel of the present embodiment is similar or identical to the structure of the semiconductor device 100 of the above described embodiments.

The display panel according to an embodiment of the present application includes a semiconductor device 100, and the semiconductor device 100 uses a first conductor potion, a channel potion and a second conductor potion to stack to form a vertical active structure layer to realize a narrow channel. Moreover, since the growth direction of the crystal grains provided in the channel portion is consistent with the moving direction of the carriers, a single crystal-like channel structure can be realized, thereby improving the mobility of the carriers.

The embodiments of the present application further provide a chip including the semiconductor device 100 according to any one of the above-described embodiments. That is, the structure of the semiconductor device of the chip of the present embodiment is similar or identical to the structure of the semiconductor device 100 of the above-described embodiment.

The chip according to an embodiment of the present application includes a semiconductor device 100, wherein the semiconductor device 100 adopts a first conductor potion, a channel potion and a second conductor potion stacked to form a vertical active structure layer to realize a narrow channel. Moreover, since the growth direction of the crystal grains provided in the channel portion is consistent with the moving direction of the carriers, a single crystal-like channel structure can be realized, thereby improving the mobility of the carriers.

The above describes in detail a semiconductor device, a display panel, and a chip according to some embodiments of the present application. The principles and embodiments of the present application are described by using specific examples. The description of the above embodiments is merely provided to help understand the method and the core idea of the present application. Meanwhile, according to the idea of this application, there may be changes in the specific implementation and application scope for those skilled in the art. In summary, the present description should not be understood as limitation on the application.

What is claimed is:

1. A semiconductor device, comprising:
a substrate; and
at least one thin film transistor disposed on the substrate; wherein the thin film transistor comprises:
an active structure layer disposed on the substrate, wherein the active structure layer comprises a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier.

2. The semiconductor device of claim 1, wherein a slope angle of the active structure layer ranges from 80° to 90°.

3. The semiconductor device of claim 1, wherein a thickness of the channel portion ranges from 5 nm to 1 mm.

4. The semiconductor device of claim 2, wherein the gate electrode comprises a first gate electrode and a second gate electrode, the first gate electrode is located on a side of the active structure layer, and the second gate electrode is located on another side of the active structure layer;
wherein in the direction parallel to the extension direction of the substrate, a side of the first conductor portion, a side of the channel portion, and a side of the second conductor portion are overlapped with the first gate electrode; another side of the first conductor portion, another side of the channel portion, and another side of the second conductor portion are overlapped with the second gate electrode.

5. The semiconductor device of claim 4, wherein a thickness of the first insulating layer is less than a thickness of the first conductor portion.

6. The semiconductor device of claim 4, wherein the active structure layer comprises a first side and a second side oppositely disposed, the first gate electrode covers a side of the first insulating layer facing the first side, the second gate electrode covers a side of the first insulating layer facing the second side, the first insulating layer comprises a top portion, and the top portion covers a side of the active structure layer away from the substrate;
in an orthographic projection direction of the semiconductor device, the first gate electrode and the second gate electrode are flush with a side of the top portion away from the substrate.

7. The semiconductor device of claim 1, wherein at least two the thin film transistors are provided, and in an orthographic projection of the semiconductor device, the gate electrode and the active structure layer are alternately arranged at intervals along a first direction, wherein the first direction is perpendicular to a direction of a long axis of the channel portion;
each of the at least two thin film transistors comprises two gate electrodes, wherein in a same thin film transistor, one of the two gate electrodes is disposed on a side of the active structure layer, and other one of the two gate electrodes is disposed on another side of the active structure layer; and
the first electrode, the second electrode, and the gate electrode are shared by two adjacent thin film transistors.

8. The semiconductor device of claim 7, wherein the semiconductor device further comprises a first connecting portion provided in a same layer as the first conductor portion, the first connecting portion is connected to a side of first conductor portions of the at least two thin film transistors, and the first electrode is connected to the first connecting portion through a first via;
the semiconductor device further comprises a second connecting portion provided in a same layer as the second conductor portion, the second connecting portion is connected to a side of second conductor portions of the at least two thin film transistors, and the second electrode is connected to the second connecting portion through a second via.

9. The semiconductor device of claim 8, wherein the semiconductor device further comprises a third connecting portion provided in a same layer as the gate electrode, the third connecting portion is connected to a side of gate electrodes of the at least two thin film transistors;
in an orthographic projection direction of the semiconductor device, a second insulating layer is provided between the first connecting portion and the third connecting portion, the second insulating layer covers the first connecting portion and exposes the first conductor portion, and the third connecting portion is provided on a side of the second insulating layer away from the substrate.

10. The semiconductor device of claim 9, wherein the semiconductor device further comprises a fourth connecting portion and a fifth connecting portion, the fourth connecting portion is provided in a same layer as the first conductor portion, and the fourth connecting portion is connected to another side of the first conductor portions of the at least two thin film transistors;
the fifth connecting portion is provided in a same layer as the channel portion, and the fifth connecting portion is connected to a side of the channel portions of the at least two thin film transistors;
the second connecting portion, the fourth connecting portion, and the fifth connecting portion extend in the first direction, wherein the second connecting portion, the fourth connecting portion, and the fifth connecting portion are overlapped in the orthographic projection direction of the semiconductor device.

11. The semiconductor device of claim 9, wherein the channel portion and the second conductor portion extend in the direction of the long axis of the channel portion and cover a part of the second insulating layer.

12. The semiconductor device of claim 9, wherein the first connecting portion, the fourth connecting portion and the first conductor portion are made of a same material and formed integrally, the second connecting portion and the second conductor portion are made of a same material and formed integrally, the third connecting portion and the gate electrode are made of a same material and formed integrally, and the fifth connecting portion and the channel portion are made of a same material and formed integrally.

13. A display panel, comprising a semiconductor device, wherein the semiconductor device comprises:
a substrate; and
at least one thin film transistor disposed on the substrate; wherein the thin film transistor comprises:
an active structure layer disposed on the substrate, the active structure layer comprises a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier, wherein a slope angle of the active structure layer ranges from 80° to 90°.

14. The display panel of claim 13, wherein a thickness of the channel portion ranges from 5 nm to 1 mm.

15. The display panel of claim 14, wherein the gate electrode comprises a first gate electrode and a second gate electrode, wherein the first gate electrode is located on a side of the active structure layer, and the second gate electrode is located on another side of the active structure layer;
wherein in the direction parallel to the extension direction of the substrate, one side of the first conductor portion, one side of the channel portion, and one side of the second conductor portion are overlapped with the first gate electrode; another side of the first conductor portion, another side of the channel portion, and another side of the second conductor portion are overlapped with the second gate electrode.

16. The display panel of claim 15, wherein a thickness of the first insulating layer is less than a thickness of the first conductor portion.

17. A chip comprising a semiconductor device, wherein the semiconductor device comprises:
a substrate; and
at least one thin film transistor disposed on the substrate; wherein the thin film transistor comprises:
an active structure layer disposed on the substrate, the active structure layer comprises a first conductor portion, a channel portion, and a second conductor portion, wherein the first conductor portion is disposed on the substrate, the channel portion is disposed on a side of the first conductor portion away from the substrate, and the second conductor portion is disposed on a side of the channel portion away from the substrate;
a first insulating layer, wherein the first insulating layer covers the active structure layer and the substrate;
a gate electrode, wherein the gate electrode is disposed on the first insulating layer and disposed on at least one side of the active structure layer, and the gate electrode is overlapped with at least a side of the channel portion in a direction parallel to an extension direction of the substrate; and
a first electrode and a second electrode, wherein the first electrode is connected to the first conductor portion, and the second electrode is connected to the second conductor portion;
wherein a material of the channel portion is polysilicon, and a growth direction of a crystal grain of the polysilicon is consistent with a moving direction of a carrier, wherein a slope angle of the active structure layer ranges from 80° to 90°.

18. The chip of claim 17, wherein a thickness of the channel portion ranges from 5 nm to 1 mm.

19. The chip of claim 18, wherein the gate electrode comprises a first gate electrode and a second gate electrode, wherein the first gate electrode is located on a side of the active structure layer, and the second gate electrode is located on another side of the active structure layer;
wherein in the direction parallel to the extension direction of the substrate, one side of the first conductor portion, one side of the channel portion, and one side of the second conductor portion are overlapped with the first gate electrode; another side of the first conductor portion, another side of the channel portion, and another side of the second conductor portion are overlapped with the second gate electrode.

20. The chip of claim 19, wherein a thickness of the first insulating layer is less than a thickness of the first conductor portion.
